(19) United States
(12) Patent Application Publication
(10) Pub. No.: US 2002/0064946 A1
(43) Pub. Date: May 30, 2002

(54) Field effect transistor with silicide gate

(76) Inventor: Christoph Wasshuber, Parker, TX (US)

Correspondence Address: TEXAS INSTRUMENTS INCORPORATED, P O BOX 655474, M/S 3999, DALLAS, TX, 75265

(21) Appl. No.: 09/982,653

(22) Filed: Oct. 18, 2001

Related U.S. Application Data
(60) Provisional application No. 60/250,526, filed on Nov. 30, 2000.

(51) Int. Cl. H01L 21/44; H01L 29/76; H01L 29/94; H01L 31/062; H01L 31/113; H01L 31/119

(52) U.S. Cl. 438/655; 257/377; 438/657

(57) ABSTRACT

Field effect transistor 22 comprises a gate insulator layer 12 formed on an outer surface of substrate 10. Composite gate stack 24 comprises the gate insulator layer 12, a silicide layer 18 and a polycrystalline semiconductor layer 20. Silicide layer 18 is formed by reacting an inner polycrystalline semiconductor layer 16 and a metal layer 14. Silicide layer 18 reduces carrier depletion effect because of its higher carrier density.

### TECHNICAL FIELD OF THE INVENTION

This invention relates in general to the field of electronic devices and more particularly to an improved field effect transistor having a silicide gate portion and a method of producing the same.

### BACKGROUND OF THE INVENTION

The overall performance of modern day integrated electronic systems ultimately relies in part on the ability to create smaller and faster field effect transistors formed in a monolithic integrated system. As field effect transistors are designed to be smaller and smaller, new physical constraints limit their performance. For example, as the gate electrode of a field effect transistor is designed to be smaller and smaller and the demands of the integrated system require the transistor to operate at higher switching speeds, the effects of carrier depletion within the gate electrode become more and more of a design constraint.

Carrier depletion is the gradual migration of both electrons and holes out of the gate electrode and into the channel region of a field effect transistor. This migration of carriers from the gate electrode increases the effective thickness of the gate oxide by depleting the electronic carriers from an area of the gate electrode proximate the gate oxide. This effective increase in gate oxide thickness decreases the effective capacitance associated with the gate oxide. This decrease in gate oxide capacitance decreases the ability of the field effect transistor to turn on. The depletion of the gate electrode is exacerbated by the decrease in the gate oxide thickness and the decrease in the volume of the gate electrode that is associated with the reduction in the thickness of the gate oxide and the volume of the gate electrode associated with the reduction in overall size of the field effect transistor associated with the design of smaller and smaller field effect transistors.

The depletion of the gate electrode is typically associated with the use of doped polycrystalline silicon as the preferred material from which gate electrodes are constructed. The depletion effect has been addressed through the use of metal gate electrodes. However, the use of metal in gate electrodes dramatically changes the work function of the overall field effect device and greatly complicates the construction of the gate electrode field effect device.

As such, a need has arisen for a method of constructing a field effect transistor that utilizes polycrystalline semiconductor material to construct the gate electrode but which does not suffer from carrier depletion effects associated with smaller gate electrode geometries.

### SUMMARY OF THE INVENTION

In accordance with the teachings of the present invention, a field effect transistor having a polycrystalline semiconductor gate electrode is described that substantially eliminates or reduces disadvantages associated with prior gate electrode architectures.

According to one embodiment of the present invention, a semiconductor device is provided which comprises a gate insulator formed outwardly from the surface of a semiconductor substrate. A gate electrode is formed outwardly from an outer surface of the gate insulator layer. The gate electrode comprises a layer of polycrystalline semiconductor material doped so as to render the gate electrode conductive. The gate electrode further comprises a layer of silicide material which is disposed between the gate insulator layer and the polycrystalline gate layer. The silicide layer provides an abundant supply of electronic carriers near the gate insulator layer and therefore reduces the carrier depletion effect associated with operation of the device.

### BRIEF DESCRIPTION OF THE DRAWINGS

A more complete understanding of the present invention may be acquired by referring to the detailed description in conjunction with accompanying figures in which like reference numbers indicate like features and wherein:

FIGS. 1A through 1C are a series of greatly enlarged elevational cross-sectional diagrams indicating the structure and method of construction of a field effect transistor formed according to the teachings of the present invention.

### DETAILED DESCRIPTION OF THE INVENTION

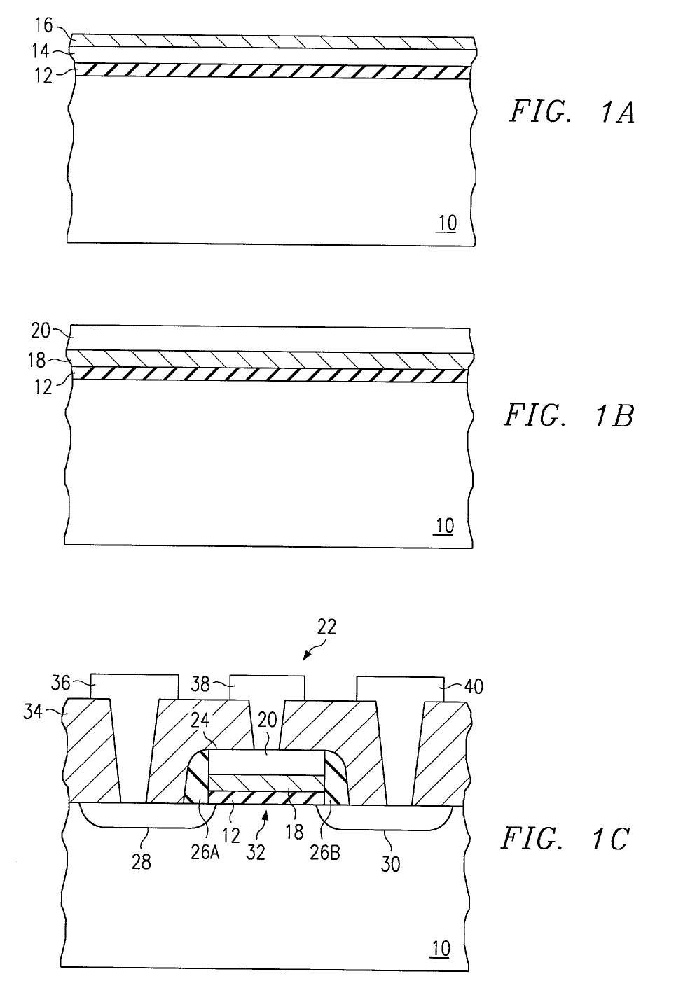

Referring to FIG. 1A, a semiconductor substrate 10 is indicated. Semiconductor substrate 10 may comprise a semiconductor layer comprising silicon, gallium arsenide or other suitable single crystalline, polycrystalline, or amorphous semiconductor layer. A gate insulator layer 12 is formed on an outer surface of semiconductor layer 10. Gate insulator layer 12 may be comprised of a semiconductor oxide grown on the outer surface of layer 10 to a depth on the order of 20 angstroms. For example, if layer 10 comprises single crystalline silicon, gate insulator layer 12 may comprise on the order of 20 angstroms of silicon dioxide formed on the outer surface of layer 10. The formation of layer 12 may comprise a number of known techniques such as the formation of sacrificial oxide layers prior to the formation of the actual gate insulator layer 12.

Referring again to FIG. 1A, an inner polycrystalline semiconductor layer 14 is deposited on an outer surface of gate insulator layer 12. Inner polycrystalline semiconductor layer 14 may comprise, for example, a layer of polycrystalline silicon deposited to a depth on the order of 15 nanometers.

Referring again to FIG. 1A, a metal layer 16 is then deposited on the outer surface of inner polycrystalline semiconductor layer 14. Metal layer 16 may comprise any suitable metal which is capable of forming a silicide upon reaction with layer 14. For example, layer 16 may comprise cobalt, titanium, nickel, or silver. Specifically, layer 16 may comprise a layer of cobalt deposited to a depth on the order of 10 nanometers.

Following the deposition of metal layer 16, the substrate 10 and the layers 12, 14 and 16 are subjected to a process where the structure is heated to on the order of 600° centigrade for a sufficient period of time to react the metal layer 16 and the polycrystalline semiconductor layer 14 to form an inner silicide layer 18 shown in FIG. 1B. Following the reaction, inner silicide layer 18 will comprise, for example, a layer of cobalt silicide on the order of 20 nanometers in thickness disposed on the outer surface of gate insulator layer 12. The materials necessary to form a suitable gate electrode are then completed through the deposition of an outer polycrystalline semiconductor layer 20 on the outer surface of silicide layer 18 as shown in FIG. 1B. Outer polycrystalline semiconductor layer 20 may comprise, for example, on the order of 1,500 Angstroms of polycrystalline silicon which is doped either during its deposition or following its deposition with a sufficient amount of impurities such as boron or phosphorous ions to render it conductive. According to an alternate embodiment of the present invention, layer 20 could be deposited on the outer surface of layer 16 prior to the silicidation process. Layer 18 could then be formed by reacting the entire structure including layer 20.

The gate electrode layers 18 and 20 and the gate oxide layer 12 are then formed into a finished field effect transistor indicated generally at 22 through the formation of additional structures shown in FIG. 1C. First, the gate oxide layer 12, silicide layer 18 and outer polycrystalline semiconductor layer 20 are etched together to form a composite gate stack 24 indicated in FIG. 1C. Sidewall insulator bodies 26A and 26B are then formed through the deposition of a layer of insulative material such as silicon dioxide, silicon intride, or a combination thereof. The deposited layer is then the anisotropically etched, resulting in the formation of sidewall bodies 26A and 26B shown in FIG. 1C. Subsequently, a source/drain region 28 and a source/drain region 30 are then formed by implanting impurities into the outer surface of substrate 10 proximate the outer boundaries of sidewall insulator bodies 26A and 26B. The formation of source/drain region 28 and source/drain region 30 defines a channel region 32 in the substrate 10 near its outer surface separating region 28 and region 30 and proximate an inner surface of gate oxide layer 12.

The field effect transistor 22 is completed through the formation of an isolation insulator layer 34 and the creation of a source/drain contact 36, a gate contact 38 and a source/drain contact 40. Isolation insulator layer 34 may comprise a sufficient depth of insulative material such as silicon dioxide or silicon nitride. Contacts 36, 38 and 40 are constructed through the formation of openings in layer 34 followed by the deposition and patterning of conductive layer which may comprise, for example, aluminum or copper.

The resulting field effect transistor 22 includes a silicide layer 18 between the polycrystalline gate layer 20 and the gate oxide layer 12. Silicide layer 18 is positioned and constructed of a material so that it serves to greatly reduce or eliminate the potential effects of carrier depletion during the operation of field effect device 22. This is due to the fact that silicide layer 18 has a much higher carrier density than ordinarily associated with even highly doped polycrystalline semiconductor materials such as that within outer polycrystalline semiconductor layer 20. The abundant supply of electronic carriers within layer 18 will result in the maintenance of the effective oxide thickness through the operation of field effect device 22. As a result, field effect transistor 22 will maintain the same or substantially the same operational parameters throughout its operational life as contrasted with a transistor which contains a gate electrode formed entirely of doped polycrystalline semiconductor material. Accordingly, a field effect transistor is constructed that eliminates or substantially reduces the effect of carrier depletion without having to use a metal gate electrode. While the exclusive use of metals to construct a gate electrode such as aluminum or copper will control the effect of carrier depletion, these techniques are much more costly due to the difficulties in working with the aluminum or copper material. According to the present invention, carrier depletion effects may be addressed without changing substantially the work function of the overall device and without having to complicate and necessarily increase the expense of the methods used to form the device.

Although the present invention has been described in detail, it should be understood that various changes, modifications, alterations and substitutions may be made to the teachings described herein without departing from the spirit and scope of the present invention which is solely defined by dependent claims.

What is claimed is:

1. A transistor formed proximate an outer surface of a semiconductor layer, comprising:
a gate insulator layer disposed outwardly from the outer surface of semiconductor layer;
a composite gate electrode disposed outwardly from the gate insulator layer and separated from the outer surface of the semiconductor layer by the gate insulator layer, the composite electrode comprising an inner layer of silicide material adjacent the outer surface of the gate insulator layer; and
first and second source/drain regions disposed in the semiconductor layer near opposing sides of the gate insulator layer so as to define a channel region in the semiconductor layer disposed between the first and second source/drain regions and adjacent the inner surface of the gate insulator layer.

2. The transistor of claim 1 wherein the composite gate electrode further comprises a layer of polycrystalline semiconductor material disposed outwardly from the inner layer of silicide material.

3. The transistor of claim 1 wherein the semiconductor substrate comprises single crystalline silicon.

4. The transistor of claim 1 wherein the gate insulator layer comprises silicon dioxide.

5. The transistor of claim 1 wherein the silicide layer of the composite gate electrode is formed through the reaction of a metal chosen from the group consisting of cobalt, titanium, nickel and silver.

6. The transistor of claim 2 wherein the polycrystalline semiconductor layer comprises silicon.

7. A field effect transistor formed proximate an outer surface of a semiconductor layer, comprising:
a gate oxide layer disposed outwardly from the outer surface of semiconductor layer;
a composite gate electrode disposed outwardly from the gate insulator layer and separated from the outer surface of the semiconductor layer by the gate insulator layer, the composite electrode comprising an inner layer of silicide material adjacent the outer surface of the gate insulator layer and a layer of doped polycrystalline semiconductor material disposed outwardly from the layer of silicide material; and
first and second source/drain regions disposed in the semiconductor layer near opposing sides of the gate insulator layer so as to define a channel region in the semiconductor layer disposed between the first and second source/drain regions and adjacent the inner surface of the gate insulator layer.

8. The transistor of claim 7 wherein the silicide layer of the composite gate electrode is formed from the reaction of a metal chosen from the group consisting of cobalt, titanium, nickel and silver.

9. A method of forming a field effect transistor proximate an outer surface of a semiconductor layer comprising:
forming a gate insulator layer on an outer surface of the semiconductor layer;
forming a silicide layer adjacent the outer surface of the gate insulator layer; and
forming a gate stack from the gate insulator layer and the silicide layer.

10. The method of claim 9 and further comprising the step of depositing an outer polycrystalline semiconductor layer outwardly from an outer surface of the silicide layer to form a composite gate electrode.

11. The method of claim 9 and further comprising:
forming first and second source/drain regions in the semiconductor layer disposed proximate opposite edges of the gate stack and defining a channel region of the semiconductor layer disposed between the first and second source drain regions.

12. The method of claim 9 and further comprising:
forming an isolation insulator layer outwardly from the semiconductor layer and the gate stack;
forming first and second source/drain contacts and a gate contact comprising conductive material and contacting, respectively, first and second source/drain regions and the gate stack.

13. The method of claim 9 wherein the step of forming a silicide layer comprises the steps of:
depositing a layer of metal on the outer surface of the gate insulator layer;
depositing an inner polycrystalline semiconductor layer on the outer surface of the metal layer; and
heating the metal layer and the inner polycrystalline semiconductor layer to react the metal layer with the inner polycrystalline semiconductor layer to form the silicide layer.

14. The method of claim 9 wherein the step of depositing a layer of metal comprises the step of depositing a layer of material chosen from the group consisting of cobalt, titanium, nickel and silver.
